(19) United States
(12) Patent Application Publication
(10) Pub. No.: US 2011/0174374 A1
(43) Pub. Date: Jul. 21, 2011

(54) HETEROJUNCTION SOLAR CELL WITH ABSORBER HAVING AN INTEGRATED DOPING PROFILE

(75) Inventor: Nils-Peter Harder, Hameln (DE)

(73) Assignee: Institut fur Solarenergieforschung GmbH, Emmerthal (DE)

(21) Appl. No.: 13/002,089

(22) PCT Filed: Jun. 30, 2009
(86) PCT No.: PCT/EP2009/058148

§ 371 Date: Mar. 8, 2011

(30) Foreign Application Priority Data
Jul. 1, 2008 (DE) 10 2008 030 693.2

(51) Int. Cl. H01L 31/0376; H01L 31/0264; H01L 31/036; H01L 31/0352

(52) U.S. Cl. 136/258; 136/261; 438/87; 257/E31.039

(57) ABSTRACT

The invention relates to a heterojunction solar cell and a method for the production thereof. The heterojunction solar cell has an absorber layer made of silicon with a basic doping and at least one heterojunction layer of a doped semiconductor material whose band gap differs from that of the silicon of the absorber layer. The absorber layer has a doped layer at an interface directed toward the heterojunction layer, the doping concentration of said doped layer being greater than the basic doping concentration of the absorber layer. As a result of this doping profile, a field effect can be caused which prevents charge carrier pairs produced within the absorber layer from diffusing toward the interface between the absorber layer and the heterojunction layer and from recombining there.

### FIELD OF THE INVENTION

The present invention relates to a heterojunction solar cell and a production method for such a heterojunction solar cell.

### BACKGROUND OF THE INVENTION

Solar cells serve to convert light into electrical energy. In order to be able to spatially separate the charge carrier pairs generated by incident light in a solar cell substrate, the solar cell comprises different adjacent semiconductor regions, the individual regions having electrical properties which differ from each other due to the energy band structure of the semiconductor materials used for the regions and/or due to the nature and concentration of the doping agents introduced into the particular semiconductor material. Due to these different electrical properties, an electrical potential difference is established at the interface between the different semiconductor regions, on the basis of which the electrons and holes of the light-generated charge carrier pairs are spatially separated.

A distinction is made generally between so-called homojunction solar cells and so-called heterojunction solar cells. Homojunction solar cells in general comprise a single semiconductor substrate of a semiconductor material in which the adjacent different semiconductor regions are produced by local introduction of different doping agents. For example, in a substrate of silicon a region doped with boron of the p-semiconductor type can be adjacent, i.e. can abut, to a region doped with phosphorus of the n-semiconductor type, so that a pn junction forms at the interface, which in its turn again generates the potential difference necessary to separate the charge carriers.

In contrast to this, heterojunction solar cells have adjacent regions which are made of different semiconductor materials. Since the valency bands and conduction bands of the different semiconductor materials lie at different energy levels, so-called “band offsets” arise at the interface to which the different semiconductor materials are adjacent, and in general also a band bending, which can cause the potential difference desired for separation of the charge carriers. This effect can be furthermore assisted in that the individual semiconductor materials in their turn can again be doped, which leads to additional influences on the band bending.

The semiconductor materials used for formation of the heterojunction solar cell can on the one hand differ with respect to the chemical elements used for this. For example, layers of different semiconductor-forming elements, such as silicon, germanium, gallium arsenide etc., can be deposited on top of one another. However, semiconductor materials of the same chemical elements but in different crystalline or amorphous structures can also be used. For example, it is known that silicon can have very different electrical properties depending on whether it is in the crystalline or in the amorphous state, that is to say that inter alia the energy levels of the valency and conduction bands or the edges thereof and the band gaps lying in between can differ significantly.

FIG. 1a shows a conventional heterojunction solar cell 101, in which on an absorber layer 103 of crystalline silicon (c-Si), on a surface facing the incident light during use, a further semiconductor layer, which is called heterojunction layer 105 here, is deposited. The heterojunction layer 105 comprises amorphous silicon (a-Si) and is doped such that it is of the opposite semiconductor type to the absorber layer 103. The heterojunction layer 105 thus forms an emitter for the absorber layer 103. At the interface between the heterojunction layer 105 and the absorber layer 103, the desired potential difference for separation of the charge carrier pairs is generated due to the band bendings or band offsets which occur there. In the example shown, a further heterojunction layer 107 is deposited on the opposite surface of the absorber layer 103. This is of the same semiconductor type as the absorber layer 103, but the doping concentration is higher, so that this heterojunction layer 107 can serve as a back surface field (BSF).

FIG. 1b shows the position-dependent doping concentration C for the regions of the heterojunction solar cell 101 which are shown in FIG. 1a. In this context, FIG. 1b is presented such that the regions to be assigned to the individual layers 103, 105, 107 can be seen directly by comparison with FIG. 1a. As can be seen from FIG. 1b, the change in the doping concentration C at the interfaces between the individual heterojunction layers 105, 107 and the absorber layer 103 is abrupt. In particular at the interface where the essentially homogeneously doped absorber layer of the n-semiconductor type or p-semiconductor type is adjacent to the likewise essentially homogeneously doped heterojunction layer 105 of the correspondingly opposite p-semiconductor type or n-semiconductor type serving as an emitter layer and a high potential difference is thus formed, there is an abrupt transition from a doping of the one semiconductor type to a doping of the correspondingly other semiconductor type.

FIG. 2a shows a further example of a conventional heterojunction solar cell 151. In this heterojunction solar cell 151, between an absorber layer 153 and a heterojunction layer 155 on the front side, serving as an emitter layer, and a heterojunction layer 157 on the rear side, serving as a BSF layer, in each case an additional, intrinsic amorphous semiconductor layer 159, 161 is inserted. The insertion of such intrinsic layers 159, 161, which are not doped or are very weakly doped (e.g. <1×10¹⁶ cm⁻³) can have the effect that the more highly doped emitter layer 153 is no longer directly adjacent to the still more highly doped heterojunction layers 155, 157. The space charge regions or potential bendings arising at the transitions are widened in this manner and the highly doped heterojunction layers, which typically do not have very long charge carrier life times, are in this way spatially separated from the absorber volume by the non-doped or weakly doped intermediate layer.

It has been observed that if the preparation is good the heterojunction solar cell structure shown in FIG. 2a has a relatively high surface passivation quality, which can lead to a correspondingly higher open circuit voltage than is the case with the solar cell structure shown in FIG. 1a. The quality of the surface passivation as a rule increases in this context with increasing thickness of the intrinsic layers 159, 161 of amorphous silicon. Typical thicknesses of such intrinsic layers 159, 161 are in the range of from 0.5 nm to 10 nm.

However, it has also been observed that in the case of heterojunction solar cells prepared as shown in FIG. 2a, the fill factor was hitherto always relatively low compared with the fill factors observed in the case of the solar cell structure shown in FIG. 1a.

The observation that in the case of the heterojunction solar cell structure shown in FIG. 2a on the one hand the open circuit voltage is higher than in the case of the structure shown in FIG. 1a, but on the other hand the fill factor observed is lower can be explained inter alia in the following manner: The intrinsic a-Si layer 159, 161 has a considerably higher electronic quality than the doped a-Si heterojunction layers 105, 155, 107, 157. That is to say the recombination activity in/of the intrinsic layer is lower than in the doped a-Si heterojunction layers. The effective surface recombination due to the use of an intrinsic a-Si heterojunction layer 159, 161 directly adjacent to the c-Si absorber layer 153 is consequently lower (better) than in the case of the solar cell structure shown in FIG. 1a, in which a doped a-Si heterojunction layer 105, 107 is directly adjacent to the c-Si absorber layer 153. On the other hand, the current transport within the solar cell is impeded by the intrinsic layer(s). For simplification, a “series resistance” of the intrinsic layer 159, 161 can be referred to. This additional “series resistance” can lead to a reduction in the fill factor and therefore to losses in efficiency for the solar cell.

### SUMMARY OF THE INVENTION

There may therefore be a need for a heterojunction solar cell in which inter alia the problems described above which occur in conventional heterojunction solar cells are at least partly reduced. In particular, there may be a need for a heterojunction solar cell which has on the one hand a good effective surface passivation and associated with this a high open circuit voltage, and on the other hand a high fill factor due to low series resistances. Furthermore, there may be a need for a production method for such a heterojunction solar cell.

This need may be met by the subject matter of the independent claims. Advantageous embodiments of the present invention are described in the dependent claims.

According to a first aspect of the present invention, a heterojunction solar cell is proposed which has an absorber layer of silicon with a base doping and at least one heterojunction layer of a doped semiconductor material, the band gap of which differs from that of the silicon of the absorber layer. In this context, the absorber layer has a doped layer at an interface directed towards the heterojunction layer, the doping concentration of the doped layer being higher than the base doping concentration of the absorber layer.

This first aspect of the present invention can be regarded as being based on the following concept:

Starting from the conventional heterojunction solar cells described above, in a further development an absorber layer which is essentially homogeneously doped per se with respect to its base doping no longer passes abruptly at its interface into a heterojunction layer which is likewise in turn essentially homogeneously doped per se, but the doping concentration within the absorber layer changes, preferably continuously, towards the interface with the heterojunction layer. In the absorber layer an increased doping agent concentration therefore prevails in the vicinity of the surface thereof.

For example, the doping agent concentration of the base doping in the actual absorber which is optimum for the mode of action of a solar cell is typically in the range of from 1×10¹⁴ cm⁻³ to 1×10¹⁶ cm⁻³, but can also be lower, so that in the extreme case the absorber can also be made of intrinsic material. On one surface of the absorber layer, which later forms the interface to the adjacent heterojunction layer or, alternatively, to an intrinsic layer additionally arranged in between, a layer with an increased doping concentration increasing, for example, towards the interface, with a maximum doping concentration for example in the range of from 1×10¹⁷ cm⁻³ to 1×10¹⁹ cm⁻³, is formed locally or over the entire area. The thickness of this comparatively highly doped layer is low, for example less than 2 μm, so that the recombination, which is increased due to the increased doping, within the relatively small proportion of the volume of this layer compared with the total volume of the absorber makes no significant contribution to the total recombination in the absorber.

The “field effect” resulting from the doping profile close to the surface nevertheless leads to one kind of charge carrier, that is to say either the holes or the electrons, being kept away from surface defect states such as occur, for example, at the interface between the absorber layer and the heterojunction layer. This effect is also called “field effect passivation” and implies a physical description of the effective surface passivation based on an electrical field. The high doping close to the surface leads in this context to a corresponding band bending which causes a corresponding electrical field close to the surface, which in turn keeps one kind of charge carrier from reaching the surface and the recombination centres present there.

The inventors of the present invention have found that such a “field effect passivation” can be advantageously used in the formation or production of heterojunction solar cells. As a result of it being possible to keep charge carriers away from the interface between the absorber layer and heterojunction layer due to the field effect, it is possible for lesser requirements to be imposed on the passivating properties of the heterojunction layer or on the quality of the interface. While in conventional heterojunction solar cells, such as are shown, for example, in FIG. 1a, both recombination due to defects at the interface between the absorber layer and the heterojunction layer and recombination within the volume of the heterojunction layer have a considerable influence on the overall properties of the particular heterojunction solar cell, and in particular on its open circuit voltage, these influences are greatly moderated in the heterojunction solar cell proposed here. Due to the field effect caused by the high doping close to the surface, the charge carriers generated within the absorber layer can for the most part no longer diffuse to the surface of the absorber and recombine at the recombination centres present there. The requirement with respect to a very low surface recombination at the interface between the absorber layer and the heterojunction layer, such as is conventionally chiefly to be achieved in that there should be as few recombination centres as possible both at the interface and within the heterojunction layer, which in turn can be achieved in that the heterojunction layer should be deposited as defect-free as possible—and therefore slowly and cost-intensively—or an additionally intrinsic layer should be inserted between the absorber layer and the heterojunction layer, can thus be reduced.

In the case of the heterojunction solar cells proposed here, it therefore appears to be possible to be able to leave out, or at least be able to make thinner, the inserted intrinsic layer currently usually integrated into conventional heterojunction solar cells, without a deterioration in the electrical properties of the solar cell occurring. This can contribute to the series resistance which occurs in conventional heterojunction solar cells, due to the inserted intrinsic layer, being absent or being reduced, which can lead to an increase in the fill factor and therefore in the efficiency of the solar cell.

A further advantageous effect in the case of the heterojunction solar cell described herein can be seen in the following state of affairs. In conventional heterojunction solar cells in which the heterojunction layer is configured as an emitter and the absorber layer as a base, the space charge region, which forms at the pn junction arising and in which the electron and hole concentration correspond to one another, is in the region of the interface between the absorber layer and the heterojunction layer. The interface defect states which occur virtually unavoidably at this interface therefore lie in the space charge region, which is particularly susceptible to recombination. In the heterojunction solar cell presented here, however, the position of the pn junction is decoupled from that of the heterojunction. The emitter here is in fact not formed merely by the heterojunction layer, but additionally also by the doped layer introduced close to the surface in the absorber layer, this doped layer in this specific embodiment likewise forming a part of the emitter. The actual pn junction is thus shifted into the low-defect region of the absorber layer.

Further features, details and possible advantages of embodiments of the solar cell according to the invention are explained in the following.

The absorber layer can be any desired layer of silicon doped in a base doping. In this context, the base doping can be e.g. in a region of 10¹⁶ cm⁻³, but it can also be lower, and in the extreme case even so low, for example in the region of 10¹³ cm⁻³, that intrinsic silicon can be assumed. The absorber layer can be provided in the form of a silicon wafer. Alternatively, the absorber layer can also be provided as a thin film of silicon. The absorber layer has a thickness such that a considerable content of incident light, in particular sunlight, is absorbed within the absorber layer. For example, the absorber layer can have a thickness of more than 5 μm, preferably more than 20 μm and, in the case of a silicon wafer, preferably more than 100 μm.

The absorber layer can be doped with any desired doping agents. For example, the silicon of the absorber layer can be doped with boron, so that p-type silicon results. Alternatively, phosphorus can be used for the doping, so that n-type silicon results.

According to one embodiment of the present invention, the absorber layer comprises crystalline silicon, also called c-Si. Various crystallinities, such as, for example, monocrystalline, multicrystalline or polycrystalline silicon, can be used in this context. Crystalline silicon has, compared to amorphous silicon, for example, a low density of defects which could act as recombination centres, and therefore has a high electronic quality.

The heterojunction layer differs from the absorber layer in particular with respect to the doped semiconductor material used for it. The band gap of the semiconductor material of the heterojunction layer differs from that of the silicon of the absorber layer. This difference can exist both in the size of the band gap and in the energy position of the band gap, for example based on the Fermi energy level. As a rule, the band gap of the heterojunction layer is greater than that of the absorber layer. The semiconductor material of the heterojunction can accordingly comprise either silicon, although with a different doping to the silicon of the absorber layer or with a different structure or crystallinity, or it can comprise completely different semiconductor materials, such as, for example, germanium, gallium arsenide etc.

According to one embodiment of the present invention, the heterojunction layer comprises amorphous silicon. Such amorphous silicon has a larger band gap (E_{gap}=1.5-2.1 eV, depending on the production) than that of crystalline silicon (E_{gap}=1.1 eV). In particular, if the heterojunction layer is constructed as an emitter layer with a doping opposite to the absorber layer, the use of amorphous silicon may have an advantageous effect on the open circuit voltage of the solar cell. Alternatively, the formation of a BSF by means of a heterojunction layer of amorphous silicon can have an advantageous effect on the open circuit voltage.

One or more heterojunction layers can be provided on various part surfaces of the absorber layer. For example, a heterojunction layer serving as an emitter can be arranged on a front side and/or alternatively on a rear side of the absorber layer. Alternatively or in addition to this, a heterojunction layer serving as a BSF can be arranged on part surfaces of the absorber layer. The thickness of the heterojunction layer in this context can be considerably lower than the thickness of the absorber layer, and, for example, less than 1 μm, preferably less than 100 nm and more preferably in the range of 5-50 nm.

The absorber layer differs from that such as is used in conventional heterojunction solar cells inter alia in that additional doping agents are introduced at an interface directed towards the heterojunction layer in order to produce a doped layer, the doping concentration of which is higher than the base doping concentration of the absorber layer. The more highly doped layer is therefore part of the absorber layer, but has a higher doping agent concentration than the remainder of the absorber layer. The type of doping agent and the doping agent concentration can be chosen in this context such that the same semiconductor type as in the heterojunction layer is established in the region of the doping profile. In other words, this means that when the heterojunction layer is constructed, for example, as an emitter layer with a semiconductor type opposite to the absorber layer, additional doping agents can be introduced at the boundary layer between the absorber layer and heterojunction layer such that, for example, the homogeneous base doping of the absorber layer is over-compensated locally in the region of the interface and an emitter-like doping profile is thus established there. Alternatively, if the heterojunction layer is provided, for example, as a BSF with a doping corresponding to the absorber layer originating from the semiconductor type, merely the base doping of the absorber layer may be increased locally in the region of the boundary layer.

According to one embodiment of the present invention, the doped layer within the absorber layer has a maximum doping agent concentration of between 1×10¹⁷ cm⁻³ and 1×10²⁰ cm⁻³, preferably 1×10¹⁸ cm⁻³ and 1×10¹⁹ cm⁻³. Such a maximum concentration of doping agent on the one hand can lead to charge carriers, which are generated inside the absorber layer, being kept away from the interface to the heterojunction layer due to the field effect arising, and on the other hand the doping agent concentration is low enough so that the additional charge carrier recombination such as occurs in highly doped semiconductor regions is kept low, in particular the depth of the doping profile is kept low enough.

According to a further embodiment of the present invention, the doped layer has a doping profile (23, 25) with a doping agent concentration decreasing in a direction directed away from the interface. In other words, the doping in a region further inside the absorber layer is lower than further towards the surface thereof.

According to a further embodiment of the present invention, the doped layer has a doping profile such as is produced by diffusion processes. In other words, this means that the doping agent concentration decreases in a direction away from the interface in a manner such as is typical in the case of diffusion profiles produced by diffusion of doping agents. Such doping profiles on the one hand are easy to produce with standard techniques in silicon wafers, and on the other hand have proved themselves for a long time in the production of homojunction solar cells due to their advantageous electronic properties.

According to a further embodiment of the present invention, the doped layer has a depth of less than 3 μm, preferably less than 1 μm and more preferably less than 0.5 μm. The doping profile can therefore have a thickness or depth which is considerably smaller than the thickness of the absorber layer and which furthermore is preferably also lower than the thickness of the heterojunction layer.

According to a further embodiment of the present invention, the heterojunction layer is directly adjacent to the absorber layer. As described above, in the case of conventional heterojunction solar cells an intrinsic semiconductor layer has often been inserted between the absorber layer and the heterojunction layer in order to reduce the recombination losses at the interface between the two layers. Due to the doping profile proposed here in the region of the absorber layer close to the interface and due to the associated field effect, in the proposed heterojunction solar cell, however, provision of an additional layer of intrinsic semiconductor material may advantageously be dispensed with, without considerable losses in solar cell efficiency due to interface recombination occurring. However, it is pointed out that in addition a layer of intrinsic semiconductor material inserted between the heterojunction layer and the absorber layer may additionally be provided.

According to a further aspect of the present invention, a method for the production of a heterojunction solar cell is proposed, the method comprising the following steps: providing an absorber layer of silicon essentially homogeneously doped in a base doping; introducing of doping agents into the absorber layer to produce a doped layer, the doping concentration of which is higher than the base doping concentration of the absorber layer; and depositing a heterojunction layer of a doped semiconductor material, the band gap of which differs from that of the silicon of the absorber layer, on to the surface of the absorber layer.

The wording “essentially homogeneously doped silicon” for the absorber layer may be understood here as meaning that the silicon used as the base material for the absorber layer is not to be purposely provided with a doping profile. However, it is not to be ruled out that the doping agent concentration within the silicon used for the absorber layer locally varies slightly, as is partly unavoidable in particular due to external and intrinsic influences during production of the silicon. For example, the doping agent concentration within the essentially homogeneously doped silicon should vary by not more than one order of magnitude.

The doping agents for producing the layer, which is more highly doped and close to the surface, within the absorber layer may be introduced in various ways. Preferably, the doping agents are introduced by diffusion. For this, doping agents can be brought into the vicinity of the surface of the absorber layer for example in gaseous, liquid or solid form and diffused into the surface of the material of the absorber layer at elevated temperatures.

After the additional doping profile has been produced, the heterojunction layer can be deposited on to the surface of the absorber layer, in particular where the additional doping agents have been introduced beforehand. This can be effected with the aid of any desired coating or epitaxy process, such as, for example, chemical vapour deposition (CVD), in particular plasma enhanced CVD (PECVD), physical vapour deposition (PVD) or liquid phase epitaxy (LPE).

It is noted that the embodiments, features and advantages of the invention have been described chiefly with respect to the heterojunction solar cell according to the invention. However, a person skilled in the art will see from the preceding and also from the following description that, unless stated otherwise, the embodiments and features of the invention can also be applied analogously to the production process according to the invention for a heterojunction solar cell, and vice versa. In particular, the features of the various embodiments can also be combined with one another in any desired manner.

### BRIEF DESCRIPTION OF THE DRAWINGS

Further features and advantages of the present invention will be seen by the person skilled in the art from the following description of embodiments which are given by way of example but are not to be interpreted as limiting the invention, and with reference to the accompanying drawings.

FIG. 1a shows a conventional heterojunction solar cell in cross-section.

FIG. 1b shows the doping profile of the heterojunction solar cell shown in FIG. 1a.

FIG. 2a shows a further conventional heterojunction solar cell with integrated intrinsic semiconductor layers in cross-section.

FIG. 2b shows the doping profile of the heterojunction solar cell shown in FIG. 2a.

FIG. 3a shows a heterojunction solar cell according to one embodiment of the present invention in cross-section.

FIG. 3b shows the doping profile of the heterojunction solar cell shown in FIG. 3a.

FIG. 4a shows a heterojunction solar cell according to a further embodiment of the present invention with integrated intrinsic semiconductor layers in cross-section.

FIG. 4b shows the doping profile of the heterojunction solar cell shown in FIG. 4a.

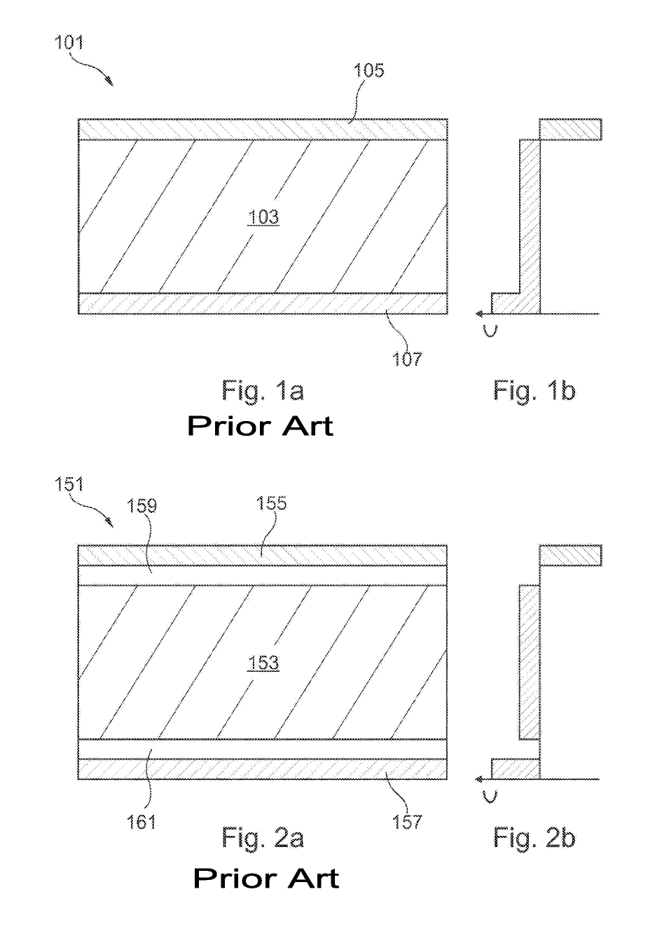

All the figures are merely diagrams and are not true to scale. In the figure, similar or identical elements are labelled with the same reference signs.

### DETAILED DESCRIPTION OF PREFERRED EMBODIMENTS

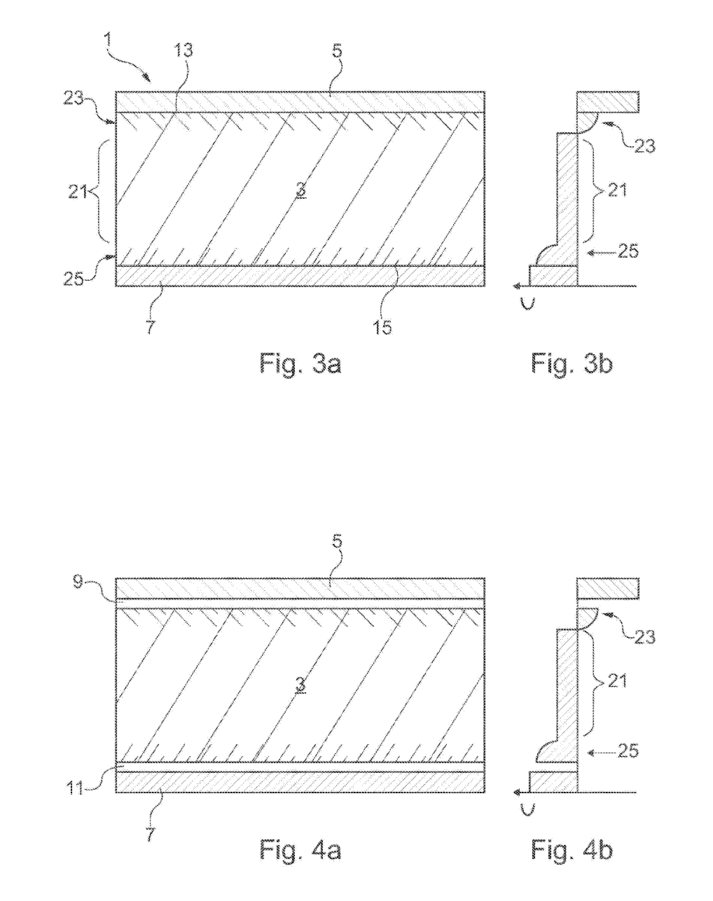

FIG. 3a shows a heterojunction solar cell 1 according to one embodiment of the present invention. An absorber layer 3 of crystalline silicon is doped, as shown in diagram form in the diffusion profile shown in FIG. 3b, homogeneously in a p-type manner in a central region 21. A doped layer 23, 25 with a doping profile is additionally introduced in regions close to the surface. As can be clearly seen in FIG. 3b and is also shown in diagram form by the nature of the shading in FIG. 3a, the doping agent concentration C in each case decreases in the direction away from the interface 13, 15 of the absorber layer 3 and towards the inside of the absorber layer 3. The nature of the presentation of the doping concentration chosen in FIG. 3b (and 1b, 2b and 4b) is to be understood as meaning that the doping concentration of the one type (for example n-type) is shown to the left of the centre of the graph and the doping concentration of the other type is shown to the right of the centre of the graph. In this context, the doping type in FIGS. 3a and 3b in the front region 23 is opposite to the doping type in the central region 21 and therefore has emitter-like properties compared with the base-like central region 21. The doping type in the rear region 25 corresponds to that of the central region 21, so that a BSF-like region is formed there.

For example, the homogeneously doped central region 21 can already be doped with boron during the production of the absorber, for example in the form of a crystalline silicon wafer, whereas the additional doped regions 25, 23 can be produced by subsequent diffusion of additional boron or phosphorus. Essentially non-doped absorbers can also be employed.

Heterojunction layers 5, 7 are deposited on at the interfaces 13, 15 of the absorber 3, both on the front side and on the rear side. These layers each have a doping concentration which is largely homogeneous per se, and the doping type of the particular heterojunction layer 5, 7 corresponds to that doping type such as prevails at the particular interface of the absorber layer 3 on to which the heterojunction layer 5, 7 is deposited. The doping agent concentration within the emitter-like heterojunction layer 5 on the front side is considerably higher than the surface doping agent concentration within the adjacent region 23 of the doping profile introduced into the absorber layer 3. A corresponding description applies to the base-like heterojunction layer 7 arranged on the rear side.

In the heterojunction solar cell shown in FIG. 4a/b according to a further embodiment of the present invention, an additional intrinsic layer 9 is inserted on the front side between the absorber layer 3 and the emitter-like heterojunction layer 5. Furthermore, an additional intrinsic layer 11 is inserted on the rear side between the absorber layer 3 and the base-like heterojunction layer 7. The intrinsic layers 9, 11 can contribute towards a further reduction of recombination losses in the region of the transition from the absorber layer 3 to one of the heterojunction layers 5, 7. However, their positive influence is probably less than in conventional heterojunction solar cells, such as are shown, for example, in FIG. 2a, due to the additional doping profile provided within the absorber layer 3 and due to the field effect caused by this.

Finally, it is pointed out that the terms “include”, “comprise” etc. do not rule out the presence of further elements. The term “a” or “one” also does not rule out the presence of a plurality of objects. The reference signs in the claims serve merely for ease of reading and are not intended to limit the scope of protection of the claims in any way.

1. Heterojunction solar cell, comprising:
an absorber layer of silicon with a base doping concentration;
a heterojunction layer of a doped semiconductor material, the band gap of which differs from that of the silicon of the absorber layer;
wherein the absorber layer has, at an interface directed towards the heterojunction layer, a doped layer, the doping concentration of which is higher than the base doping concentration of the absorber layer.

2. Solar cell according to claim 1,
wherein the absorber layer comprises crystalline silicon.

3. Solar cell according to claim 1,
wherein the heterojunction layer comprises amorphous silicon.

4. Solar cell according to claim 1,
wherein the doped layer within the absorber layer has a maximum doping agent concentration of between 1×10¹⁷ cm⁻³ and 1×10²⁰ cm⁻³.

5. Solar cell according to claim 1,
wherein the doped layer has a doping profile with a doping agent concentration decreasing in a direction directed away from the interface.

6. Solar cell according to claim 1,
wherein the doped layer has a doping profile resulting from diffusion processes.

7. Solar cell according to claim 1,
wherein the doped layer has a depth of less than 2 μm.

8. Solar cell according to claim 1,
wherein the heterojunction layer directly abuts to the absorber layer.

9. Solar cell according to claim 1,
wherein an intrinsic layer is inserted between the heterojunction layer and the absorber layer.

10. Solar cell according to claim 1,
wherein the heterojunction layer and the doped layer of the absorber layer comprise the same semiconductor type.

11. Method for the production of a heterojunction solar cell,
wherein the method comprises:
providing an absorber layer of silicon essentially homogeneously doped with a base doping;
introducing of doping agents into the absorber layer to produce a doped layer, the doping concentration of which is higher than the base doping concentration of the absorber layer;
depositing of a heterojunction layer of a doped semiconductor material, the band gap of which differs from that of the silicon of the absorber layer, on to the surface of the absorber layer.

12. Method according to claim 11,
wherein the doped layer is produced with a doping profile with a doping agent concentration decreasing in a direction directed away from a surface of the absorber layer.

13. Method according to claim 11,
wherein the doping agents are introduced by diffusion.
